(19) United States
(12) Patent Application Publication
(10) Pub. No.: US 2016/0027682 A1
(43) Pub. Date: Jan. 28, 2016

(54) MANUFACTURING METHOD FOR A SEMICONDUCTOR DEVICE

(71) Applicant: Kabushiki Kaisha Toshiba, Tokyo (JP)

(72) Inventors: Shintaro Okujo, Oita Oita (JP); Kenichi Yoshino, Oita Oita (JP); Hiroyuki Fukumizu, Yokohama Kanagawa (JP); Satoshi Kato, Oita Oita (JP)

(21) Appl. No.: 14/636,000

(22) Filed: Mar. 2, 2015

(30) Foreign Application Priority Data
Jul. 28, 2014 (JP) 2014-153264

(51) Int. Cl. H01L 21/762; H01L 27/146

(52) U.S. Cl. CPC H01L 21/76227; H01L 27/1463

(57) ABSTRACT

According to the embodiments, a manufacturing method for a semiconductor device includes forming recessed parts on a surface of a semiconductor layer. The manufacturing method for the semiconductor device includes a process for forming a buffer layer, which has a melting point lower than that of the semiconductor layer, on a surface of the recessed part on the surface of the semiconductor layer. The manufacturing method for the semiconductor device includes a process for forming a high-melting point film, which has the melting point higher than that of the semiconductor layer, on the buffer layer and fills the recessed part with the high-melting point film. The manufacturing method for the semiconductor device includes a process for heating the semiconductor layer having the buffer layer and the high-melting point film formed thereon at a temperature equal to or higher than the melting point of the buffer layer.

### CROSS-REFERENCE TO RELATED APPLICATIONS

This application is based upon and claims the benefit of priority from Japanese Patent Application No. 2014-153264, filed on Jul. 28, 2014; the entire contents of which are incorporated herein by reference.

### FIELD

The present embodiment relates to a manufacturing method for a semiconductor device.

### BACKGROUND

Conventionally, a so-called trench isolation technique is disclosed in which a recessed part filled with an insulator separates between semiconductor elements formed on a semiconductor substrate.

There is a case where the heating treatment is performed in order to repair a damaged layer formed on the semiconductor substrate when the recessed part has been formed or in order to activate an impurity region formed on the semiconductor substrate. When the temperature of the heating treatment is high, there is a case where a semiconductor region surrounded by the recessed parts is deformed and characteristics of the semiconductor elements varies which are formed on the semiconductor region surrounded by the recessed parts. Also, there is a case where the recessed part is deformed by the deformation of the semiconductor substrate and isolation between the semiconductor regions becomes not enough.

### BRIEF DESCRIPTION OF THE DRAWINGS

FIGS. 1A to 1E are diagrams of one process of a manufacturing method for a semiconductor device according to a first embodiment;

FIGS. 2A to 2L are diagrams of one process of a manufacturing method for a semiconductor device according to a second embodiment;

FIG. 3 is a schematic diagram of a partial cross section of a semiconductor device; and

FIGS. 4A to 4D are scanning electron microscope photographs of states of a substrate surface of a semiconductor device after a heat treatment has been performed.

### DETAILED DESCRIPTION

According to the present embodiment, a manufacturing method for a semiconductor device includes a process for forming a recessed part on a surface of a semiconductor layer. The manufacturing method for the semiconductor device includes a process for forming a buffer layer, which has a melting point lower than that of the semiconductor layer, on a surface of the recessed part on the surface of the semiconductor layer. The manufacturing method for the semiconductor device includes a process for forming a high-melting point film, which has the melting point higher than that of the semiconductor layer, on the buffer layer and fills the recessed part with the high-melting point film. The manufacturing method for the semiconductor device includes a process for heating the semiconductor layer having the buffer layer and the high-melting point film formed thereon at a temperature equal to or higher than the melting point of the buffer layer.

The manufacturing method for the semiconductor device according to embodiments will be described in detail below with reference to the drawings. The present invention is not limited to these embodiments.

### First Embodiment

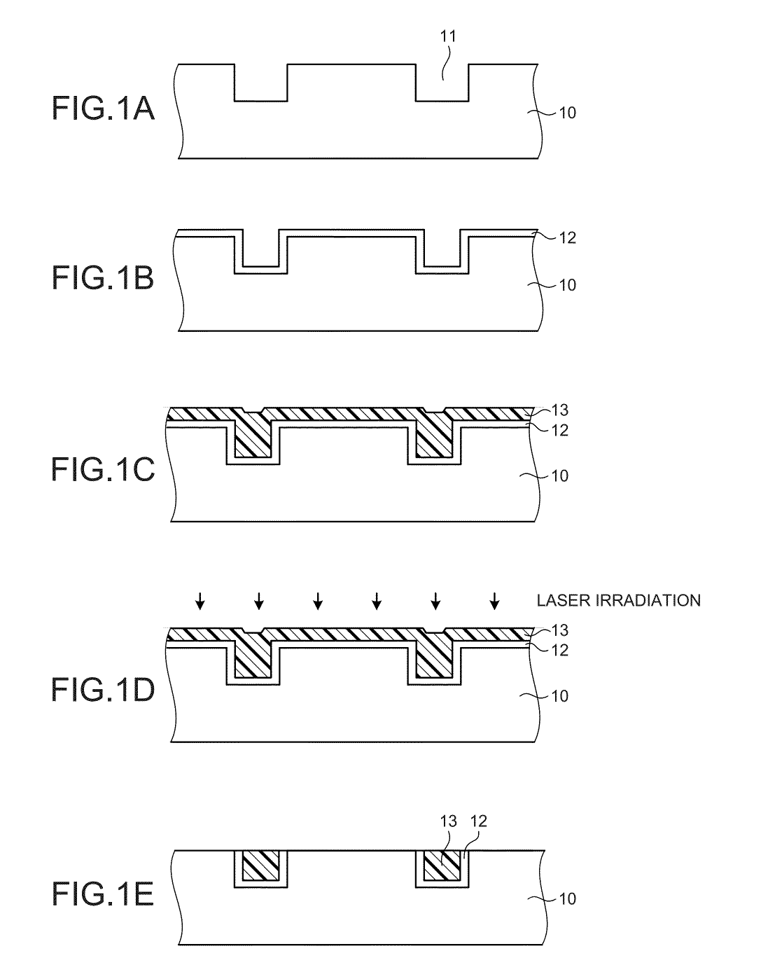

FIGS. 1A to 1E are diagrams of one process of a manufacturing method for a semiconductor device according to a first embodiment. A semiconductor substrate 10 having recessed parts 11 formed thereon is prepared (FIG. 1A). The semiconductor substrate 10 may include a semiconductor layer formed on the semiconductor substrate. The semiconductor substrate 10 is configured of, for example, silicon. The recessed part 11 is formed in a grid shape, for example, so as to separate predetermined semiconductor elements (not illustrated) from each other formed on the semiconductor substrate 10.

Next, a buffer layer 12 is formed on surfaces of the recessed parts 11 (FIG. 1B). The buffer layer 12 is, for example, an amorphous silicon layer. The amorphous silicon layer is formed, for example, by the CVD (Chemical Vapor Deposition). A film thickness of the buffer layer 12 is equal to or higher than 5 nm (nanometer), for example, the film thickness is 10 nm.

A high-melting point film 13 has the melting point higher than that of the semiconductor substrate 10. The high-melting point film 13 is formed on the buffer layer 12, and the recessed part 11 is filled with the high-melting point film 13 (FIG. 1C). The high-melting point film 13 is, for example, a silicon oxide film. The silicon oxide film is formed, for example, by the CVD.

A heating treatment by laser irradiation is performed in a state where the buffer layer 12 and the high-melting point film 13 have been formed (FIG. 1D). With this heating treatment, for example, a damaged layer (not illustrated) generated on the surface of the semiconductor substrate 10 and generated by forming the recessed part 11 is repaired. The laser irradiation is performed under the condition where at least the buffer layer 12 is melt, for example. A heating condition can be adjusted by adjusting an output of the laser and an irradiation time.

Next, the buffer layer 12 and the high-melting point film 13 formed on the surface of the semiconductor substrate 10 are removed by the CMP (Chemical Mechanical Polishing) (FIG. 1E). The recessed part 11 is filled with the buffer layer 12 and the high-melting point film 13 which are left in the recessed part 11. When the amorphous silicon layer is used as the buffer layer 12, the amorphous silicon layer is melt and crystallized according to the heating treatment by the laser irradiation. However, for convenience of the description, the same layer is illustrated in FIG. 1E.

In the present embodiment, the heating treatment is performed in a state where the buffer layer 12, which has the melting point lower than that of the semiconductor substrate 10, is formed between the semiconductor substrate 10 and the high-melting point film 13. The recessed part 11 is filled with the high-melting point film 13. With this configuration, since the buffer layer 12 is melt faster than the semiconductor substrate 10 in the heating treatment, a stress generated between the semiconductor substrate 10 and the high-melting point film 13 is relaxed. Accordingly, deformation of the semiconductor substrate 10 can be prevented.

For example, the melting point of the silicon is 1414° C. The amorphous silicon layer has the melting point which is 300° C. to 400° C. lower than that of the silicon. The melting point of the silicon oxide film is, for example, 1650° C.±75° C., and this is higher than that of the silicon substrate. Accordingly, for example, in a case where the amorphous silicon layer is used as the buffer layer 12 and the silicon oxide film is used as the high-melting point film 13, an amorphous silicon layer which is the buffer layer 12 is melt before the semiconductor substrate 10 and the high-melting point film 13 are melt. The buffer layer 12 is melt, and then, the stress generated between the semiconductor substrate 10 and the high-melting point film 13 is relaxed. Accordingly, the deformation of the semiconductor substrate 10 can be prevented.

### Second Embodiment

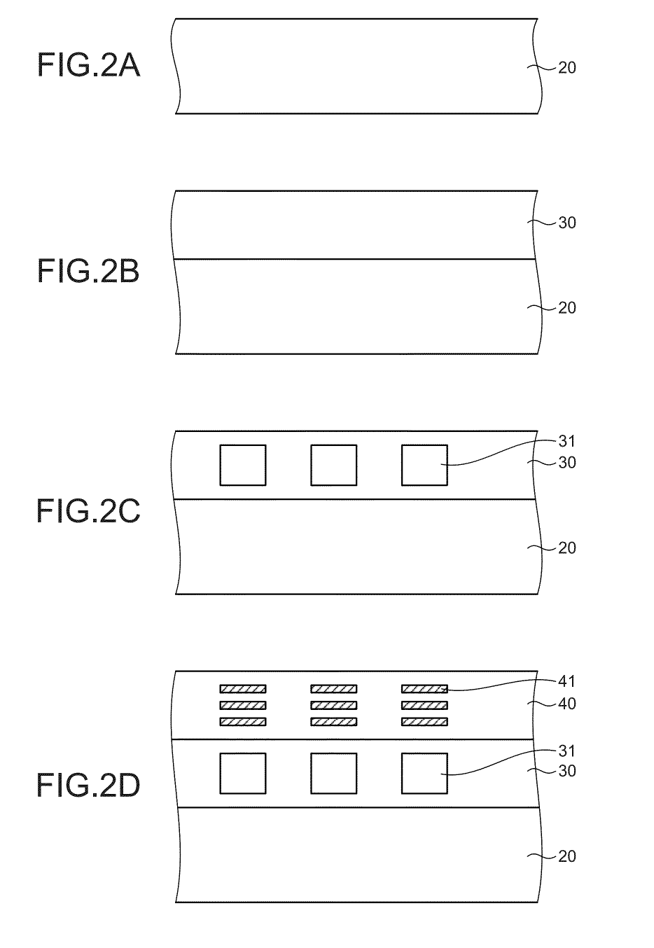

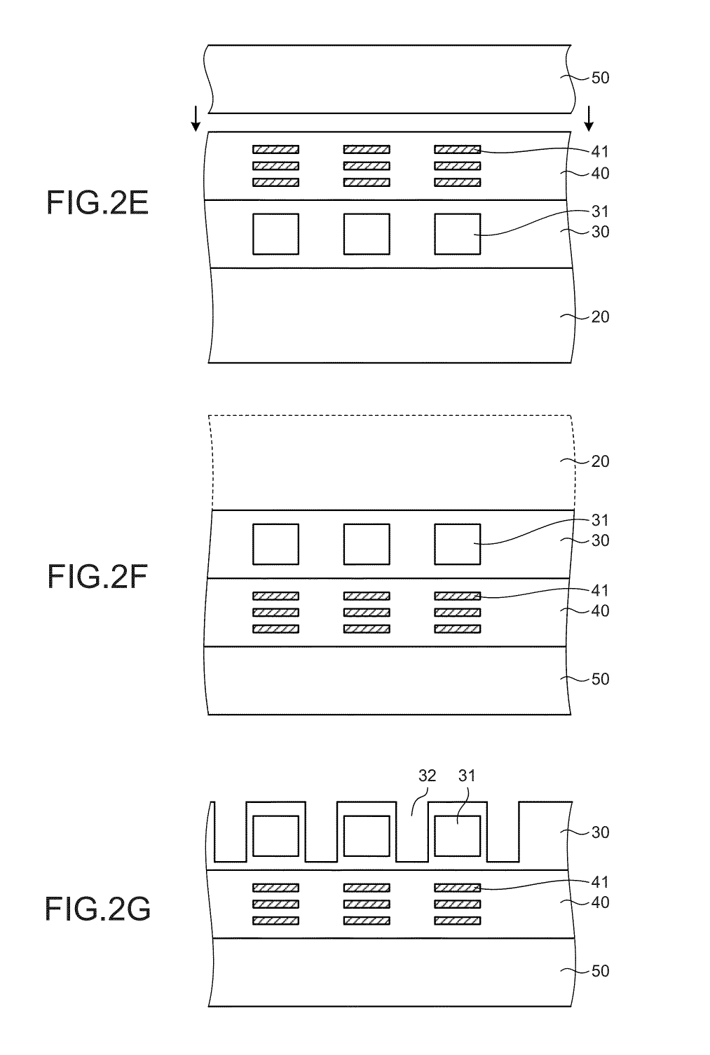

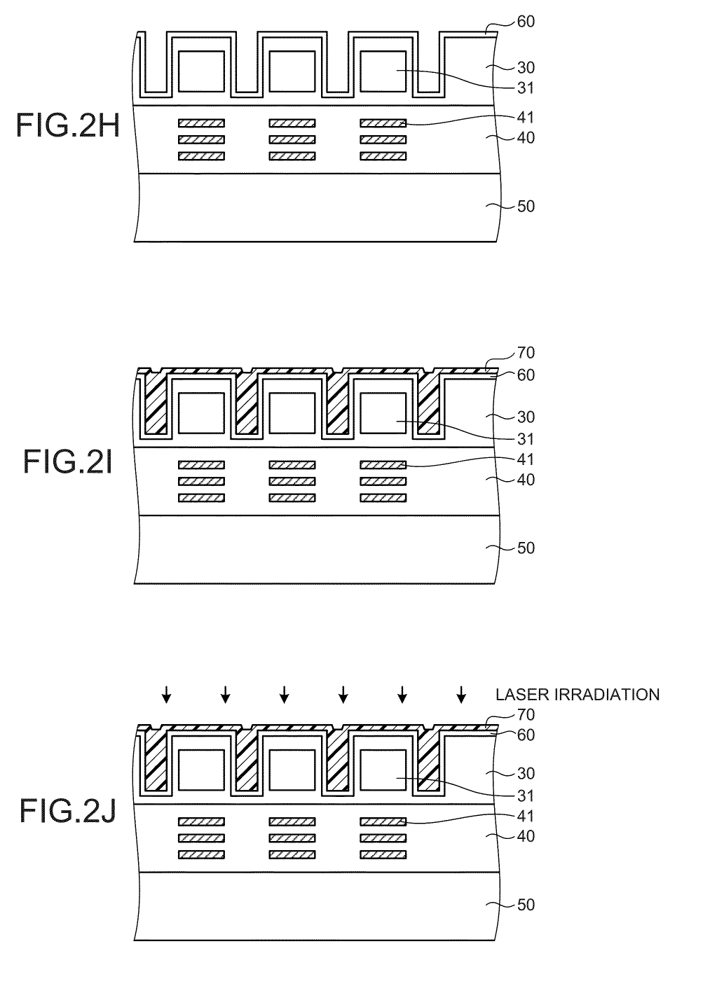

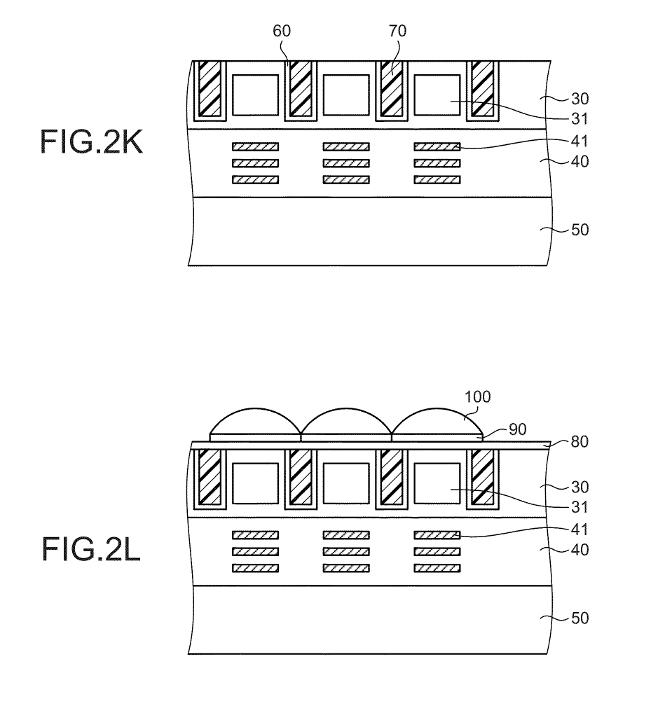

Next, a manufacturing method for a semiconductor device according to a second embodiment will be described with reference to FIGS. 2A to 2L. In the present embodiment, one embodiment of a manufacturing method for a back side illumination type CMOS image sensor will be illustrated.

A semiconductor substrate 20 is prepared (FIG. 2A). The semiconductor substrate 20 is, for example, a silicon substrate.

A semiconductor layer 30 is formed on the semiconductor substrate 20 by using an epitaxial growth method (FIG. 2B). The semiconductor layer 30 is, for example, an epitaxial silicon layer. For example, the semiconductor layer 30 is formed by the CVD.

Processes called as FEOL (Front End of Line), such as a lithography process, a film-forming process, an etching process, and an ion implantation process are repeated relative to the semiconductor layer 30. Accordingly, for example, photoelectric conversion elements 31 are formed (FIG. 2C). The photoelectric conversion element 31 is, for example, a photodiode.

Next, in a process called as BEOL (Back End of Line), an insulating film 40 is formed (FIG. 2D). The insulating film 40 has a wiring 41 formed therein, and the wiring 41 is used for an electrical connection. The wiring 41 formed in the insulating film 40 can be configured of, for example, a Cu wiring having a damascene structure. The insulating film 40 for covering the wiring 41 is, for example, a silicon oxide film formed from the TEOS (Tetra Ethyl Ortho Silicate).

Next, a support substrate 50 is formed on the insulating film 40 (FIG. 2E). The support substrate 50 is, for example, the silicon substrate. The support substrate 50 is formed on the silicon substrate by, for example, bonding it with the insulating film 40. In a bonding process, a process for cleaning a bonding surface, a process for activating the bonding surface, and the like are performed. Then, the support substrate 50 is aligned with the insulating film 40, and they are pressured and bonded. After that, an annealing treatment is performed, and bonding strength is improved.

After that, the semiconductor substrate 20 is removed (FIG. 2F). For convenience of the description, the description has been made by switching the upside and the downside of the drawing. In a process for removing the semiconductor substrate 20, for example, the CMP is used.

Sequentially, recessed parts 32 are formed on a surface of the semiconductor layer 30 (FIG. 2G). The recessed parts 32 are formed in a grid shape, for example, so as to separate between the photoelectric conversion elements 31. A color mixture or transfer of elections between the photoelectric conversion elements 31 can be prevented by separating between the photoelectric conversion elements 31 by the recessed parts 32.

Next, a buffer layer 60 is formed on the surface of the semiconductor layer 30 and an inner surface of the recessed part 32 (FIG. 2H). The buffer layer 60 has a melting point lower than that of the semiconductor layer 30. The buffer layer 60 is, for example, an amorphous silicon layer. The amorphous silicon layer is, for example, formed by the CVD. A film thickness of the buffer layer 60 is, for example, equal to or more than 5 nm. The film thickness of the buffer layer is a thickness for performing a function as a stress relaxation layer between the semiconductor layer 30 and a high-melting point film (not illustrated) formed after the buffer layer 60 when the buffer layer 60 has been melt.

A high-melting point film 70 having the melting point higher than that of the silicon is formed on the buffer layer 60 so that the recessed part 32 is filled (FIG. 21). The high-melting point film 70 is, for example, the silicon oxide film and can be formed by the CVD.

A heating treatment, for example, by laser irradiation is performed in a state where the buffer layer 60 and the high-melting point film 70 have been formed (FIG. 2J). With this heating treatment, for example, a damaged layer generated on the surface of the semiconductor substrate 30 by forming the recessed part 32 can be repaired. The heating treatment by the laser irradiation is performed under the condition where at least the buffer layer 60 is melt. The melting point of the silicon is 1414° C. The melting point of the silicon oxide film is, for example, 1650° C.±75° C., and this is higher than that of the silicon substrate. The amorphous silicon layer has the melting point which is 300° C. to 400° C. lower than that of the silicon. Accordingly, when the amorphous silicon layer is used as the buffer layer 60 and the silicon oxide film is used as the high-melting point film 70, at least the amorphous silicon layer forming the buffer layer 60 is melt and the heating treatment can be performed by appropriately setting an output of the laser irradiation and an irradiation time.

Next, the buffer layer 60 and the high-melting point film 70 formed on the surface of the semiconductor layer 30 are removed by the CMP (FIG. 2K) The recessed part 32 is filled with the buffer layer 60 and the high-melting point film 70 left in the recessed part 32. When the amorphous silicon layer is used as the buffer layer 60, the amorphous silicon layer is melt and crystallized according to the heating treatment by the laser irradiation. However, for convenience of the description, the same layer is illustrated in FIG. 2K.

Sequentially, a protective film 80 is formed on the surface of the semiconductor layer 30, the buffer layer 60, and the high-melting point film 70. The protective film 80 can be constituted by, for example, a silicon oxide film or silicon nitride film. The protective film 80 is, for example, formed by the CVD. A color filter 90 and a microlens 100 are formed on the protective film 80 so as to correspond to each photoelectric conversion element 31 (FIG. 2L).

According to the manufacturing method for the semiconductor device of the present embodiment, the heating treatment by the laser irradiation is performed in a state where the recessed part 32 is filled with the buffer layer 60 and the high-melting point film 70. The buffer layer 60 has the melting point lower than that of a silicon layer for configuring the semiconductor layer 30, and the high-melting point film 70 has the melting point higher than that of the silicon layer. A function is performed which relaxes the stress generated between the semiconductor layer 30 and the high-melting point film 70 by melting the buffer layer 60 with a lower melting point before the semiconductor layer 30 is melt. That is, the buffer layer 60 can relax the stress generated between the semiconductor layer 30 and the high-melting point film 70 by the heating treatment by the laser irradiation. Accordingly, the deformation of the semiconductor layer 30 having the photoelectric conversion elements 31 surrounded by the recessed parts 32 can be reduced, and the deformation of the semiconductor element formed on the semiconductor layer 30 can be prevented. Also, since the shape of the recessed part 32 can be maintained in a stable state by the high-melting point film 70 filled in the recessed part 32, isolation between the photoelectric conversion elements 31 formed on the semiconductor layer 30 is maintained.

In the back side illumination type CMOS image sensor, it is known that the dark current characteristics is improved as the temperature of the heating treatment to the semiconductor layer 30 having the photoelectric conversion element 31 formed therein becomes higher. According to the present embodiment, the stress is relaxed by melting the buffer layer 60, which exists between the semiconductor layer 30 and the high-melting point film 70, before melting the semiconductor layer 30, and the deformation of the semiconductor layer 30 can be prevented. Therefore, the heating treatment of the semiconductor layer 30 can be performed at a higher temperature, and the dark current characteristics of the back side illumination type CMOS image sensor can be improved. Since the deformation of the semiconductor layer 30 can be prevented, the deformation of the surface of the semiconductor layer 30 which is a light-receiving surface is prevented. Accordingly, sensitivity deterioration of the photoelectric conversion element 31 caused by the deformation of the light-receiving surface can be prevented.

In the back side illumination type CMOS image sensor, the insulating film 40 having the predetermined wiring 41 formed therein is provided to contact with the semiconductor layer 30. Therefore, it is preferable to perform the heating treatment, after the formation of the buffer layer 60 and the high-melting point film 70 on the inner surface of the recessed part 32, only on the surface of the semiconductor layer 30. By the heating treatment by the laser irradiation, the surface of the semiconductor layer 30 can be heated in a short time. Therefore, it is suitable for the heating treatment after the formation of the buffer layer 60 and the high-melting point film 70 on the inner surface of the recessed part 32.

For example, the amorphous silicon layer including boron (B) which is a p-conductivity type dopant can be used as the buffer layer 60. When the buffer layer 60 includes the p-conductivity type dopant, the buffer layer 60 becomes a diffusion source at the time of the heating treatment by the laser irradiation, and a p-conductivity type region (not illustrated) is formed in a region from the surface of the semiconductor layer 30 having contact with the buffer layer 60 (similarly to the inner surface of the recessed part 32) to a predetermined depth in the semiconductor layer 30. The formed p-conductivity type region functions as a trap layer of electrons from the damaged layer (not illustrated) in the semiconductor layer 30 which is generated, for example, when the buffer layer 60 and the high-melting point film 70 on the surface of the semiconductor layer 30 have been removed by the CMP and when the recessed part 32 has been formed. Accordingly, phenomenon can be prevented that electrons emitted from the damaged layer is supplied to the photoelectric conversion element 31.

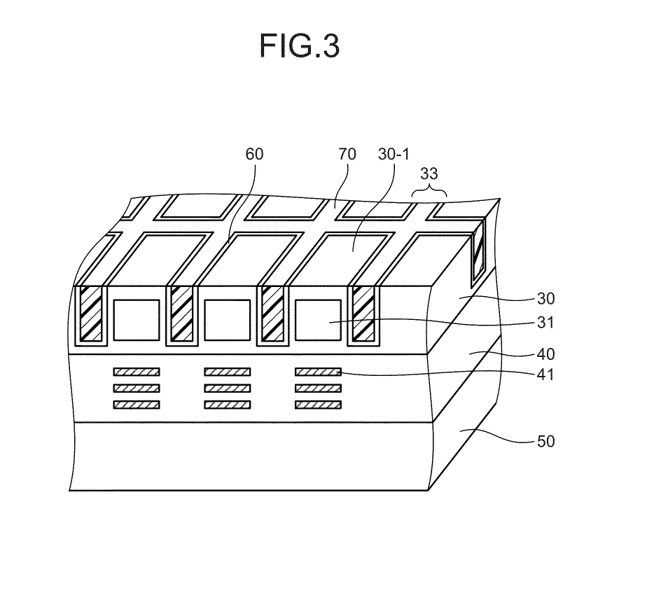

FIG. 3 is a schematic diagram of a partial cross section of the semiconductor device manufactured by the manufacturing method according to the described embodiment. Components corresponding to those of the described embodiment are denoted with the same symbols, and the redundant description regarding the components will be made as necessary. In order to illustrate a state of the separation between pixel regions 30-1 having the photoelectric conversion elements 31 formed therein, the protective film 80, the color filter 90, and the microlens 100 which are formed on the surface of the semiconductor layer 30 are omitted. The recessed part 32 is filled with the buffer layer 60 and the high-melting point film 70. For example, a separating region 33 in a grid shape formed by using the heating treatment by the laser irradiation separates between the pixel regions 30-1 having the photoelectric conversion elements 31 formed therein. When the buffer layer 60 is the amorphous silicon layer, the buffer layer 60 is crystallized according to the heat treatment by the laser irradiation. However, for convenience of the description, the layer is illustrated as the same as that before the heating treatment in FIG. 3.

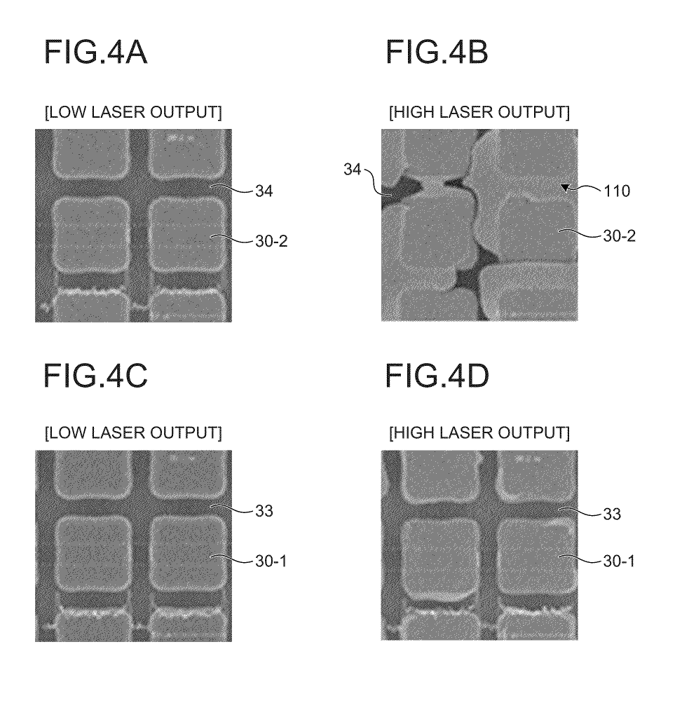

FIGS. 4A to 4D are scanning electron microscope photographs illustrating an effect of the manufacturing method for a semiconductor device according to the present embodiment. They are electron microscope photographs of the surface of the semiconductor layer 30 in which two cases of the state of the surface of the semiconductor layer 30 of the semiconductor device illustrated in FIG. 3 are compared with each other, i.e., a case where the buffer layer 60 is provided on the inner surface of the recessed part 32 formed on the semiconductor layer 30 and a case where the semiconductor layer 30 is manufactured without the buffer layer 60. The semiconductor layer 30 is an epitaxial silicon layer. FIGS. 4A and 4B on the upper stage illustrates a case where the separating region 34 is formed without providing the buffer layer 60 on the inner surface of the recessed part 32 formed in the semiconductor layer 30. A case is illustrated where the recessed part 32 formed in the semiconductor layer 30 is filled with the high-melting point film 70 not via the buffer layer 60 and the heating treatment by the laser irradiation is performed. The separating region 34 formed in a grid shape separates between pixel regions 30-2. FIGS. 4C and 4D on the lower stage illustrates a case where the separating region 33 is formed by providing the buffer layer 60 in the recessed part 32. That is, these indicate a case where the semiconductor device is manufactured according to the manufacturing method of the present embodiment. This is a case where the recessed part 32 formed on the semiconductor layer 30 is filled with the high-melting point film 70 via the buffer layer 60 and the heating treatment by the laser irradiation is performed. The separating region 33 formed in a grid shape separates between the pixel regions 30-1.

FIGS. 4A and 4C on the left side are the photos of a case where the heating treatment has been performed by a laser beam with low output. The heating treatment has been performed by the irradiation of the laser beam having an output of 1.6 J/cm2 and a wavelength of 308 nm for 170 nS (nanosecond). FIGS. 4B and 4D on the right side are the photos of a case where the heating treatment has been performed by a laser beam with high output. The heating treatment has been performed by the irradiation of the laser beam having an output of 2.1 J/cm2 and a wavelength of 308 nm for 170 nS.

When the irradiating laser output is low as indicated in FIGS. 4A and 4C, there is almost no difference between two cases, i.e., a case where the heating treatment is performed without forming the buffer layer 60 on the inner surface of the recessed part 32 (FIG. 4A) and a case where the heating treatment is performed by forming the buffer layer 60 (FIG. 4C). However, when the heating treatment has been performed with the high laser output and without providing the buffer layer 60 on the inner surface of the recessed part 32, a form change 110 can be seen (FIG. 4B). It is assumed that the form change 110 be generated by melting the silicon of the pixel region 30-2. Whereas, when the buffer layer 60 has been provided on the inner surface of the recessed part 32, the form change of the pixel region 30-1 cannot be seen even when the heating treatment is performed with the higher laser output (FIG. 4D). It is considered that the form change cannot be seen because the buffer layer 60 in the recessed part 32 has been melt before the pixel region 30-1 is melt so that the stress generated between the pixel region 30-1 and the high-melting point film 70 filled in the recessed part 32 is relaxed by the buffer layer 60, and accordingly, the deformation of the pixel region 30-1 is prevented. By preventing the form change of the pixel region 30-1, for example, when the recessed part 32 having the buffer layer 60 is used to form an element separating region of the CMOS image sensor, the deformation of the surface of the pixel region 30-1 which is a light-receiving surface is prevented, and flatness of the pixel region 30-1 is maintained. Accordingly, the sensitivity deterioration of the CMOS image sensor can be prevented. Also, since the deformation such that the silicon is melt and leaked on the separating region 33 can be prevented, the isolation between the pixel regions is maintained. Therefore, for example, the color mixture can be prevented, in which the electrons generated in the pixel region moves to and reaches the next pixel region.

The amorphous silicon layer to be the buffer layer 60 may be formed by ion implantation. The amorphous silicon layer can be formed from the inner surfaces of the recessed parts (11 and 32) to a predetermined depth in the semiconductor layers (10 and 30) by implanting ions of equal to or more than a critical dose into the inner surfaces of the recessed parts (11 and 32). The amorphous silicon layer can be formed, for example, by implanting boron (B) of equal to or more than 1×10¹⁶/cm² which is the critical dose at room temperature.

Also, instead of the amorphous silicon layer, a polycrystalline silicon layer having the melting point lower than that of the silicon substrate can be used as the buffer layer 60. The polycrystalline silicon layer melts before the silicon substrate, and accordingly, the polycrystalline silicon layer can perform a function of the buffer layer.

Instead of the silicon oxide film, a high-melting point metal such as tungsten can be used as a film to fill the recessed parts (11 and 32). Since the high-melting point metal has an excellent function to cut off the entered light, the color mixture between the photoelectric conversion elements 31 can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A manufacturing method for a semiconductor device comprising:
forming recessed parts on a surface of a semiconductor layer;
forming a buffer layer, which has a melting point lower than that of the semiconductor layer, on a surface of the recessed part on the surface of the semiconductor layer;
forming a high-melting point film, which has a melting point higher than that of the semiconductor layer, on the buffer layer and filling the recessed part with the high-melting point film; and
heating the semiconductor layer on which the buffer layer and the high-melting point film are formed at a temperature equal to or higher than the melting point of the buffer layer.

2. The manufacturing method for a semiconductor device according to claim 1, wherein
the forming the buffer layer forms the buffer layer on the surface of the semiconductor layer and the surface of the recessed part.

3. The manufacturing method for a semiconductor device according to claim 1, wherein
the buffer layer is an amorphous silicon layer.

4. The manufacturing method for a semiconductor device according to claim 1, wherein
the buffer layer is a polycrystalline silicon layer.

5. The manufacturing method for a semiconductor device according to claim 3, wherein
the amorphous silicon layer is formed by ion implantation.

6. The manufacturing method for a semiconductor device according to claim 2, wherein
the buffer layer is an amorphous silicon layer.

7. The manufacturing method for a semiconductor device according to claim 2, wherein
the buffer layer is a polycrystalline silicon layer.

8. The manufacturing method for a semiconductor device according to claim 6, wherein
the amorphous silicon layer is formed by ion implantation.

9. The manufacturing method for a semiconductor device according to claim 1, wherein
the heating the semiconductor layer includes heating by a laser.

10. The manufacturing method for a semiconductor device according to claim 2, wherein
the heating the semiconductor layer includes heating by a laser.

11. The manufacturing method for a semiconductor device according to claim 1, wherein
the buffer layer includes a p-conductivity type dopant.

12. The manufacturing method for a semiconductor device according to claim 2, wherein
the buffer layer includes a p-conductivity type dopant.

13. The manufacturing method for a semiconductor device according to claim 1, wherein
the high-melting point film is formed of a silicon oxide film.

14. The manufacturing method for a semiconductor device according to claim 2, wherein
the high-melting point film is formed of a silicon oxide film.

15. The manufacturing method for a semiconductor device according to claim 3, wherein
the high-melting point film is formed of a silicon oxide film.

16. The manufacturing method for a semiconductor device according to claim 1, wherein
the semiconductor layer includes a plurality of semiconductor elements and is provided on an insulating film in which a predetermined wiring is formed, and the recessed part is provided so as to separate the plurality of semiconductor elements one another.

17. The manufacturing method for a semiconductor device according to claim 2, wherein
the semiconductor layer includes a plurality of semiconductor elements and is provided on an insulating film in which a predetermined wiring is formed, and the recessed part is provided so as to separate the plurality of semiconductor elements one another.

18. The manufacturing method for a semiconductor device according to claim 3, wherein
the semiconductor layer includes a plurality of semiconductor elements and is provided on an insulating film in which a predetermined wiring is formed, and the recessed part is provided so as to separate the plurality of semiconductor elements one another.

19. The manufacturing method for a semiconductor device according to claim 16, wherein
the semiconductor element is a photoelectric conversion element.

20. The manufacturing method for a semiconductor device according to claim 17, wherein
the semiconductor element is a photoelectric conversion element.
